(19) United States
(12) Patent Application Publication
(10) Pub. No.: US 2026/0312597 A1
(43) Pub. Date: Oct. 8, 2026

(54) A METHOD FOR CONVERTING ANALOG SIGNALS TO DIGITAL SIGNALS

(71) Applicant: SILICON CRAFT TECHNOLOGY PUBLIC COMPANY LIMITED (SICT), Bangkok (TH)

(72) Inventors: Sitthipong WONGNAMKAM, Bangkok (TH); Samat-tachai TEPWIMONPETKUN, Lopburi (TH); Pattrakorn CHOKCHALERMWAT, Nonthaburi (TH)

(21) Appl. No.: 19/485,675

(22) PCT Filed: May 26, 2023
(86) PCT No.: PCT/IB2023/055399

§ 371 Date: Nov. 19, 2025

(51) Int. Cl. H03M 1/10; H03M 1/08

(52) U.S. Cl. CPC H03M 1/1061; H03M 1/089

(57) ABSTRACT

A method for converting analog signals to digital signals is a method to convert analog signals to digital signals in an analog-to-digital converter (ADC). The method comprises a two-step analog-to-digital conversion which can compensate for errors of the ADC reference. The method allows the use of a simple voltage reference circuit and does not require an external analog calibration probe. The method can achieve a high-accuracy ADC with a simple calibration process.

### TECHNICAL FIELD OF THE INVENTION

The present invention relates to a system for signal processing and more specifically to systems and methods for conversion of analog signals to digital signals, analog-to-digital converter (ADC) design, and digital compensation.

### BACKGROUND OF THE INVENTION

Analog-to-digital converter (ADC) is a system that converts analog signals to digital signals, and is widely used in various electronic applications such as microcontrollers, scientific instruments, sensor signal processing, image or music recording etc.

An ADC typically requires a precise voltage reference to function, which is often provided by a bandgap voltage reference circuit. This circuit provides a temperature independent voltage reference to the ADC with minimum variation over temperature and supply voltage. However, all integrated circuits (ICs) experience some variation over fabrication process, supply voltage, and temperature range, so the bandgap reference circuit requires calibration, trimming or methods to reduce errors in ADC system to account for IC process variation. To meet the stringent precision requirements of modern ADCs, the bandgap voltage reference usually needs multiple point calibrations or trimmings over the desired operation range.

The errors of the ADC reference voltage can be corrected by various methods, such as direct trimming of the voltage reference circuit using external analog probing, or indirect calibration at the output through digital compensation. Although several error correction methods have been proposed in the past, they all have certain limitations.

The U.S. Pat. No. 7,433,790B2 describes a technique for automatic reference voltage trimming that directly applies error correction to the bandgap reference circuit using an auto correction algorithm. The advantage is that it only needs external input and desired output, without the need for external probing. However, it still requires calibration at multiple temperature points and has an excessive number of design configurations, which adds to on-chip testing and support peripheral, making it more complex and occupying more area.

The U.S. Pat. No. 7,728,575B2 describes a method and apparatus for higher-order correction of a bandgap voltage. It applies error correction directly to the bandgap reference circuit, which improves accuracy and precision by correcting higher-order nonlinear errors. However, this invention also introduces more error sources and increases complexity.

The U.S. Pat. No. 9,323,274B2 describes a self-calibrating digital bandgap voltage and current reference. Although the digital bandgap reference simplifies the circuit, it requires a high-accuracy digital-to-analog converter (DAC) that needs calibration over the operating range, thereby adding complexity to the ADC.

In addition, calibration of ADCs, especially over the operating temperature range, can be time consuming and costly.

Considering these limitations, there is a need for a more effective method to minimize the amount of error in analog-to-digital converters (ADCs). The present invention addresses this issue by providing a method for reducing ADC errors that does not require external analog probes and allowing a simple voltage reference circuit to be used. This results in fewer error sources, a simpler calibration process, and reduced design complexity.

### SUMMARY OF THE INVENTION

The present invention described herein generally relates to a method for converting analog-to-digital signal (ADC) without requiring external analog calibration probes. The method involves 1) converting a first analog signal into a first digital code by using a quantizer and storing the first digital code in a digital module; 2) converting a second analog signal to be a second digital code by using the quantizer and storing the second digital code in the digital module; and 3) calculating a digital output code by using the first digital code and the second digital code wherein the digital output code represents one of the said analog signals.

The general purpose of our invention is to provide a method for converting analog signals to digital signals for both general-purpose analog-to-digital converter (ADC) and high-accuracy digital temperature sensor. The method for analog-to-digital conversion eliminates the need for external analog probes during calibration and uses a simple reference circuit, which reduces error sources, simplifies the calibration process, and lowers design complexity. The method involves a two-step analog-to-digital conversion (ADC) technique with fully digital trimming.

### BRIEF DESCRIPTION OF THE DRAWING

FIG. 1 is an example schematic diagram of a conventional bandgap voltage reference circuit.

FIG. 2 is an example diagram of a quantizer.

FIG. 3 is an example diagram of the analog-to-digital converter (ADC) according to the invention.

FIG. 4 is an example flow chart of the method to convert analog signals to digital signals according to the invention.

FIG. 5 is an example flow chart of the calibration method of the analog to digital conversion (ADC) according to the invention.

FIG. 6 is an example diagram that illustrates the effective result of the reference voltage (V_{BG}) after trimming, according to the invention.

### DETAILED DESCRIPTION

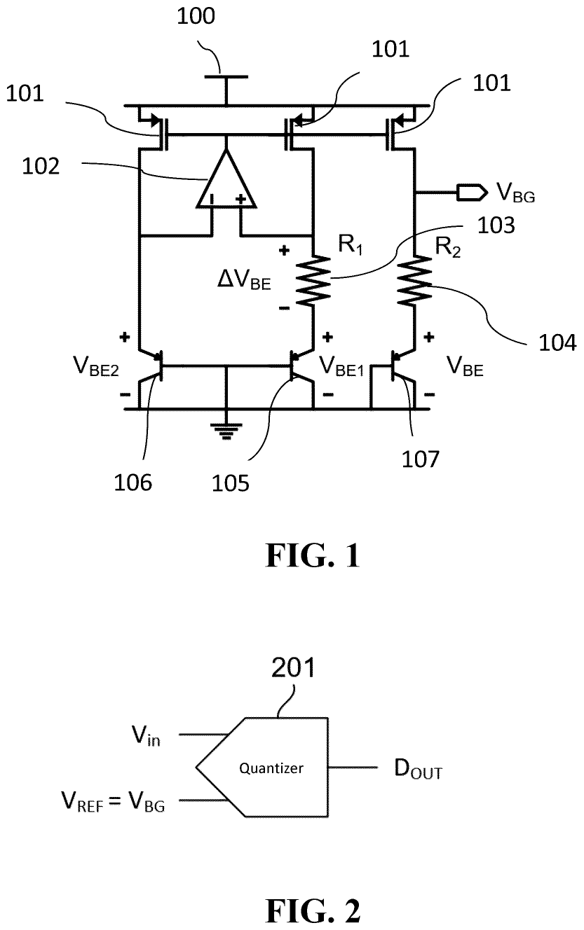

FIG. 1 shows a conventional bandgap voltage reference circuit 100 that typically consists of p-type metal oxide semiconductor field effect transistors (P-MOSFETs) 101, an operational amplifier (op-amp) 102, two resistors of a first resistor (R1) 103 and a second resistor (R2) 104, and three bipolar junction transistors (BJTs) including the first BJT 105, the second BJT 106 and the third BJT 107. The BJTs, which are biased with currents from P-MOSFETs 101, generate analog base emitter voltages (V_{BEs}). The base-emitter voltage (V_{BE}) is complementary to absolute temperature (CTAT), i.e., it decreases as the absolute temperature increases. The bipolar junction transistors (BJTs) can be replaced with semiconductor junction diodes to generate the anode-cathode voltage instead. The op-amp 102 is arranged in a negative feedback configuration, which keeps the voltages at the positive and negative input terminals of the op-amp 102 approximately equal. This voltage is equal to a second analog base-emitter voltage (V_{BE2}). A voltage difference between the first analog base-emitter voltage (V_{BE1}) and the second base-emitter voltage (V_{BE2}) can be generated by having the first BJT 105 and the second BJT 106 with different emitter areas and/or with different emitter currents. The voltage difference is known as the differential base-emitter voltage (ΔV_{BE}) which is proportional to absolute temperature (PTAT), i.e., it increases with the absolute temperature. By the circuit arrangement, the differential base-emitter voltage (ΔV_{BE}) is equal to the voltage dropped across the first resistor (R1) 103 and this creates a current flowing through the first resistor (R1) 103. The current flowing through the first resistor (R1) 103 is proportional to absolute temperature (PTAT) and is known as the PTAT current. The P-MOSFETs 101 act as a current mirror copying the current flowing through the first resistor (R1) 103 and provide the PTAT current to the second resistor (R2) 104. The output voltage of the bandgap reference circuit, which is known as the bandgap voltage (V_{BG}) can then be expressed as follow:

$${V}_{B G} = {V}_{B E} + \frac{{R}_{2}}{{R}_{1}} \cdot Δ {V}_{B E}$$

Since the differential base-emitter voltage (ΔV_{BE}) is proportional to absolute temperature (PTAT) and the analog base-emitter voltage (V_{BE}) is complementary to absolute temperature (CTAT) wherein the analog base-emitter voltage (V_{BE}) is derived by the third BJT 107, the ratio of the second resistor (R2) 104 and the first resistor (R1) 103 can be designed so that the complementary to absolute temperature (CTAT) characteristic of the analog base-emitter voltage (V_{BE}) term cancels out with the proportional to absolute temperature (PTAT) characteristic of the differential base-emitter voltage (ΔV_{BE}). This, ideally, results in the bandgap voltage (V_{BG}) that is independent of temperature. In reality, IC process variation of the BJTs and mismatch of resistors introduce variations in the absolute value of the analog base-emitter voltage (V_{BE}), and in the ratio of the second resistor (R2) 104, to the first resistor (R1) 103, respectively. This causes the bandgap voltage (V_{BG}) to be slightly temperature dependent. The ratio of the second resistor (R2) 104 and the first resistor (R1) 103 is also known as a gain factor (α) of the differential base-emitter voltage (ΔV_{BE}), which simplifies the equation of the bandgap voltage (V_{BG}) to:

$${V}_{B G} = {V}_{B E} + α \cdot Δ {V}_{B E}$$

FIG. 2 shows a diagram of a quantizer 201 that uses the bandgap voltage (V_{BG}) as a reference voltage (V_{REF}). The quantizer 201 converts an analog input voltage (Vᵢₙ) into a digital output code (Dₒᵤₜ) with the following equation:

$${D}_{o u t} = \frac{{V}_{i n}}{{V}_{R E F}} ( {2}^{N} - 1 ) = \frac{{V}_{i n}}{{V}_{B G}} ( {2}^{N} - 1 ) = \frac{{V}_{i n}}{{V}_{B E} + α \cdot Δ {V}_{B E}} ( {2}^{N} - 1 )$$

Where: N is number of bits of the quantizer 201 output.

Ideally, the bandgap voltage (V_{BG}) has a constant value (i.e., independent of temperature), the digital output code (Dₒᵤₜ) can then be related to the input voltage (Vᵢₙ), i.e., the digital code has a value that represents the analog input voltage (Vᵢₙ). Due to various error sources, the bandgap voltage (V_{BG}) will not be a constant value, which causes deviation of the digital output code (Dₒᵤₜ) from its ideal value. This deviation is known as the ADC gain error. The dominant error sources of the bandgap voltage (V_{BG}) are the analog base-emitter voltage (V_{BE}) and the gain factor (α) which come from IC process variation of the BJTs or diodes, and resistors mismatch, respectively. The analog base-emitter voltage (V_{BE}) introduces the proportional to absolute temperature (PTAT) error (i.e., the error that increases with the absolute temperature) to the digital output code (Dₒᵤₜ), which results in a temperature-dependent error. The variation in the gain factor (α) depends on the variation of resistors matching and it can introduce a complex ADC error.

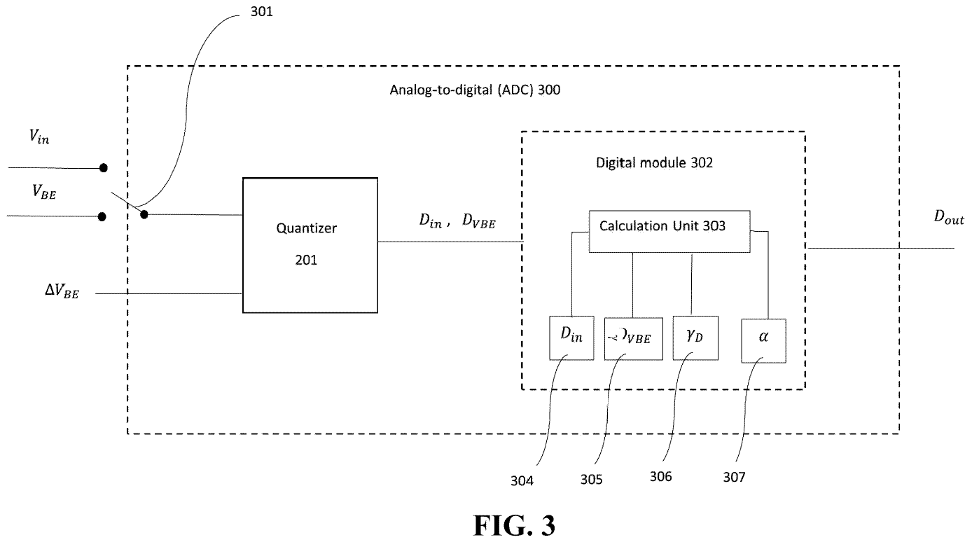

FIG. 3 shows a diagram of an ADC 300 according to the present invention. The ADC 300 comprises the quantizer 201, a switch 301, and a digital module 302. The ADC 300 has an analog input voltage terminal, an analog reference voltage terminal, and a digital output terminal. The reference input terminal of the ADC 300 is connected to the differential base-emitter voltage (ΔV_{BE}) node. The switch 301 can be configured to connect the input voltage terminal of the ADC 300 to either the analog input voltage (Vᵢₙ) or the analog base-emitter voltage (V_{BE}). The digital output terminal of the quantizer 201 is connected to the input terminal of the digital module 302. The digital module 302 comprises (a) a calculation unit 303, (b) memory units 304 and 305 and (c) non-volatile memory units 306 and 307. The digital module 302 uses at least 2 digital output codes from the quantizer 201 to perform a digital calculation to provide the digital output code (Dₒᵤₜ). The digital module 302 may use another digital code of temperature (D_{T}) to assist the digital calculation to provide the digital output code (Dₒᵤₜ).

The ADC 300 converts analog signals to digital signals by using a two-step conversion method which can be described as follows.

In the first step, two analog-to-digital conversions are performed by using at least one quantizer that uses the differential base-emitter voltage (ΔV_{BE}) as the reference voltage (V_{REF}). In a first analog-to-digital conversion, the switch 301 is configured to connect the input terminal of the quantizer 201 to the analog input voltage (Vᵢₙ) while the reference terminal of the quantizer 201 is connected to the differential base-emitter voltage (ΔV_{BE}). Thus, the digital output code of the quantizer 201 for the first conversion can be expressed by

$${D}_{i n} = \frac{{V}_{i n}}{Δ {V}_{B E}} * ( {2}^{N} - 1 )$$

Where:
N is the number of bits of the quantizer 201

In a second analog-to-digital conversion, the switch 301 is configured to connect the input terminal of the quantizer 201 to the analog base-emitter voltage (V_{BE}) while the reference terminal of the quantizer 201 is connected to the differential base-emitter voltage (ΔV_{BE}). The analog base-emitter voltage (V_{BE}) may be generated from diodes-connected the BJTs or semiconductor junction diodes biased with a constant current source (not shown). Thus, the digital output code of the quantizer 201 for the second conversion can be expressed by

$${D}_{B E} = \frac{{V}_{B E}}{Δ {V}_{B E}} * ( {2}^{N} - 1 )$$

Where:
N is the number of bits of the quantizer 201

The two digital output codes Dᵢₙ and D_{BE} are respectively stored in the memory units 304 and 305 of the digital module 302.

Note that the order of the two analog-to-digital conversions is not important. The analog input voltage (Vᵢₙ) may be converted before or after the analog base-emitter voltage (V_{BE}), or both the analog input voltage (Vᵢₙ) and the analog base-emitter voltage (V_{BE}) may be converted simultaneously using two separate quantizers 201, with one dedicated quantizer 201 for each voltage.

In the second step, the digital output code (Dₒᵤₜ) is calculated by dividing the digital code (Dᵢₙ) obtained from the analog-to-digital conversion of the analog input voltage (Vᵢₙ) by the summation of the digital code (D_{BE}) obtained from the analog-to-digital conversion of the analog base-emitter voltage (V_{BE}) and the gain factor (α).

The digital output code (Dₒᵤₜ) can be expressed by

$${D}_{O U T} = \frac{{D}_{i n}}{{D}_{B E} + {α}_{D}} * ( {2}^{N} - 1 )$$

Where α_{D}=α*(2^{N}−1) is the N-bit digital representation of the analog gain factor α. The above equation can be rearranged as follow:

$$\begin{matrix}{D}_{O U T} = \frac{{D}_{i n}}{{D}_{B E} + α * ( {2}^{N} - 1 )} * ( {2}^{N} - 1 ) \\ = \frac{\frac{{V}_{i n}}{Δ {V}_{B E}}}{\frac{{V}_{B E}}{Δ {V}_{B E}} + α} * ( {2}^{N} - 1 ) \\ = \frac{{V}_{i n}}{{V}_{B E} + α \cdot Δ {V}_{B E}} * ( {2}^{N} - 1 ) = \frac{{V}_{i n}}{{V}_{B G}} * ( {2}^{N} - 1 )\end{matrix}$$

The above equation shows that the digital output code (Dₒᵤₜ) of the ADC 300 is equivalent to the digital output code (Dₒᵤₜ) of a conventional ADC that uses the bandgap voltage (V_{BG}) as the reference voltage V_{REF}. However, the present method requires neither trimming of the bandgap voltage (V_{BG}) nor trimming of the resistor ratio to obtain a high precision ADC conversion. By using the digital calculation performed by the digital module 302, the optimum of the resistor ratio or the gain factor (α) can be corrected and stored in the non-volatile memory unit 307 of the digital module 302. The parameters of the digital correction can easily be reconfigured via a memory programming to compensate for a batch-to-batch variation.

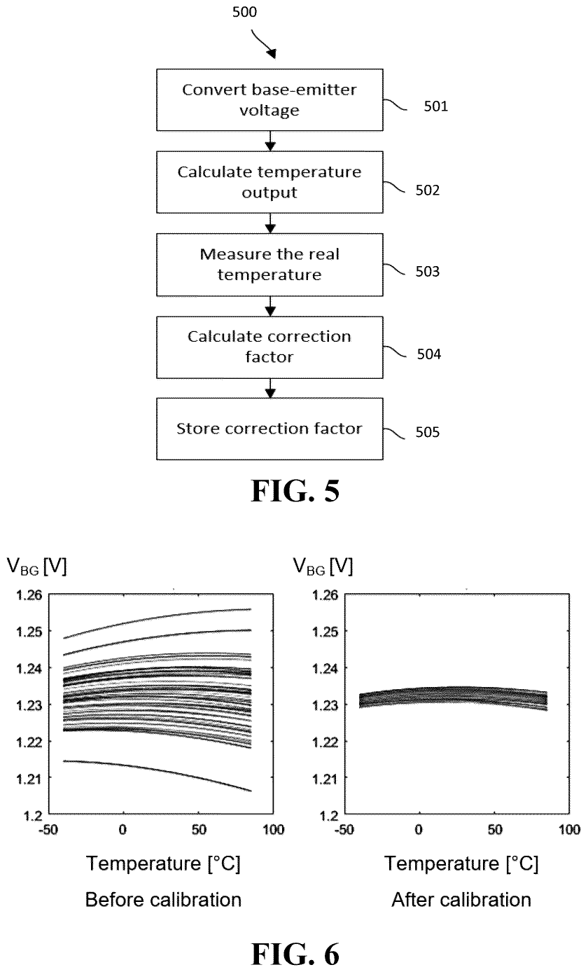

However, the residue error of the bandgap voltage (V_{BG}) is remained in V_{BE}, which can be corrected by using a correction factor (γ_{D}). The correction factor (γ_{D}) may be obtained by a calibration process and stored in the non-volatile memory unit 306 of the digital module 302. This will be explained by FIG. 5.

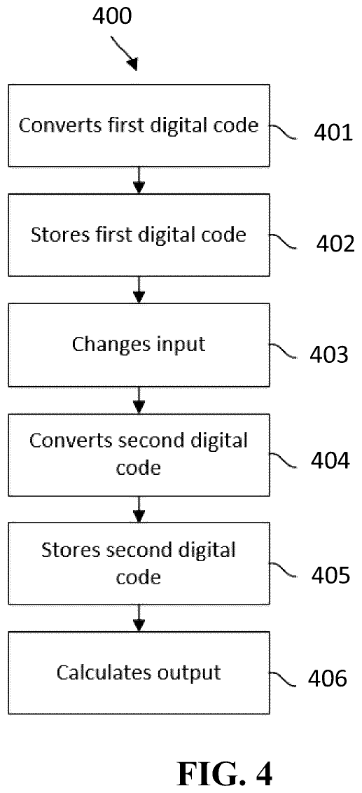

FIG. 4 shows a flow chart of a method of converting analog signals to digital signals 400 using the ADC 300 according to the present invention. In the first step 401, the switch 301 is configured to connect the input voltage terminal of the quantizer 201 to a first analog input signal (either Vᵢₙ or V_{BE}) and the quantizer 201 converts the first analog input signal (either Vᵢₙ or V_{BE}) into a first digital code (either Dᵢₙ or D_{BE}, accordingly). In the second step 402, the first digital code (either Dᵢₙ or D_{BE}) is stored in one of the memory units (either 304 or 305) of the digital module 302. In the third step 403, the switch 301 is configured to connect the input voltage terminal of the quantizer 201 to a second analog input signal (either Vᵢₙ or V_{BE}) into a second digital code (either Dᵢₙ or D_{BE}, accordingly). In the fourth step 404, the quantizer 201 converts the second analog input signal (either Vᵢₙ or V_{BE}) to a second digital code (either Dᵢₙ or D_{BE}, accordingly). In the fifth step 405, the second digital code (either Dᵢₙ or D_{BE}) is stored in one of the memory units (either 304 or 305) of the digital module 302. The first and second analog signals may be either Vᵢₙ or V_{BE}, and the first analog signal is a different signal from the second analog signal. The first and second digital codes may be either Dᵢₙ or D_{BE}, according to the first and second analog signals. The first digital code is a different code from the second digital code. The first and second digital codes are stored in two different memory units. Finally, in the sixth step 406, the output digital code (Dₒᵤₜ) of the ADC 300 is calculated by dividing the digital code (Dᵢₙ) by the summation of the digital code (D_{BE}), and the gain factor (α).

Note that, the order of the conversion is not important, the analog input voltage (Vᵢₙ) may be converted before or after the analog base-emitter voltage (V_{BE}), or both the analog input voltage (Vᵢₙ) and the analog base-emitter voltage (V_{BE}) may be converted simultaneously using individual quantizer 201 for each voltage.

A method of error correction is needed to compensate for errors in the bandgap voltage (V_{BG}), which mainly comes from errors in the analog base-emitter voltage (V_{BE}) and the gain factor (α). In the present invention, the gain factor (α) is implemented in the digital domain, thus, the error of the gain factor (α) can be compensated by adjusting the digital calculation in the digital module 302. Therefore, the error in the analog base-emitter voltage (V_{BE}) is the remaining dominant source of error in the bandgap voltage (V_{BG}). The error of the analog base-emitter voltage (V_{BE}) is largely proportional to PTAT which can be modelled as follow:

$${V}_{B E} = {V}_{B E , i d} + {V}_{err} ( T )$$

Where:
V_{BE,id} is the ideal analog base-emitter voltage (V_{BE}) characteristic without error.
Vₑᵣᵣ (T) is the PTAT error voltage of the analog base-emitter voltage (V_{BE}).

The error of the analog base-emitter voltage (V_{BE}) will affect the converted digital output code (Dₒᵤₜ) as follows:

$${D}_{B E} = \frac{{V}_{B E , i d} + {V}_{err} ( T )}{Δ {V}_{B E}} * ( {2}^{N} - 1 ) = [ \frac{{V}_{BE , id}}{Δ {V}_{B E}} + \frac{{V}_{err} ( T )}{Δ {V}_{B E}} ] * ( {2}^{N} - 1 ) = {D}_{BE , id} + {D}_{BE , err}$$

$${D}_{out} = \frac{{D}_{in}}{{D}_{B E , i d} + {D}_{B E , e r r} + {α}_{D}} * ( {2}^{N} - 1 )$$

Where:
D_{BE,id} is the ideal digital code value corresponding to the ideal analog base-emitter voltage (V_{BE,id}) without error.
D_{BE, err} is the error digital code corresponding to the PTAT error voltage (Vₑᵣᵣ (T)) of the analog base-emitter voltage (V_{BE}).

Since the digital code (D_{BE}) is temperature dependent, the digital representation of the temperature (D_{T}) can be calculated by using the following equation:

$${D}_{T} = A \frac{{α}_{D}}{{D}_{B E} + {α}_{D}} + B$$

where A and B are constant parameters, and α_{D}=α*(2^{N}−1) is the N-bit digital representation of the gain factor α.

The digital code (D_{T}) represents the temperature in degree of Kelvin. The values of A, B, and a depend on IC fabrication process and may be obtained from a curve fitting between the digital base-emitter voltage (D_{BE}) and the real temperature (Tᵣₑₐₗ) in degree of Kelvin. For an example embodiment and the process used in this invention, the values of A, B, and a are approximately 650, −6, and 11.5, respectively. The digital code of temperature (D_{T}) may represent the temperature in degree of Celsius by subtracting B with 273 (i.e., B=−279, in this case). By including the error from the analog base-emitter voltage (V_{BE}), the digital code of temperature (D_{T}) can be expressed by

$${D}_{T} = A \frac{{α}_{D}}{{D}_{B E , i d} + {D}_{B E , err} + {α}_{D}} + B$$

Next, the calibration temperature (T_{cal}) is measured by an external reference temperature sensor of the calibration system and can be expressed as follow:

$${T}_{cal} = A \frac{{α}_{D}}{{D}_{B E T c a l} + {α}_{D}} + B$$

In the calibration, D_{BETcal} is equal to D_{BE,id} thus the above equations of the digital code of temperature (D_{T}) and the calibration temperature (T_{cal}) can be rearranged as follow:

$$\frac{{V}_{err} ( T )}{α Δ {V}_{B E}} = \frac{1}{\frac{{D}_{T} - B}{A}} - \frac{1}{\frac{{T}_{cal} - B}{A}}$$

Since both Vₑᵣᵣ (T) and ΔV_{BE} are proportional to absolute temperature (PTAT), the term

$$\frac{{V}_{err} ( T )}{α Δ {V}_{BE}}$$

is approximately temperature independent. For simplicity,

$$\frac{{V}_{err} ( T )}{α Δ {V}_{B E}} = γ$$

where γ is a correction factor which is a temperature-independent constant parameter, and it represents the error of the analog signal voltage (V_{BE}).

Therefore, D_{BE} can be compensated by subtracting with D_{BE, err}, thus, D_{BE,id} can be expressed as follow:

$$\begin{matrix}{D}_{BE , id} = {D}_{BE} - {D}_{BE , err} \\ = {D}_{BE} - \frac{{V}_{err} ( T )}{Δ {V}_{BE}} * ( {2}^{N} - 1 ) \\ = {D}_{BE} - ( α \cdot γ ) * ( {2}^{N} - 1 ) \\ = {D}_{BE} = ( {α}_{D} \cdot {γ}_{D} )\end{matrix}$$

Where γ_{D}=γ*(2^{N}−1) is the digital representation of γ.

Therefore, the equation for calculating the digital output code (Dₒᵤₜ) can be modified to include the correction factor (γ_{D}) as follow:

$${D}_{outtrim} = \frac{{D}_{in}}{{D}_{B E} - ( {α}_{D} \cdot {γ}_{D} ) + {α}_{D}} * ( {2}^{N} - 1 ) = \frac{{D}_{in}}{{D}_{B E} + {α}_{D} ( 1 - {γ}_{D} )} * ( {2}^{N} - 1 )$$

The correction factor (γ_{D}) can be easily added to compensate the error of the analog base-emitter voltage (V_{BE}). In addition, since the digital code of temperature (D_{T}) represents the temperature in degree of Kelvin, this means that the converting analog signal voltage (V_{BE}) is also acts as a precision digital temperature sensor once calibrated by calculating the following equation:

$${D}_{T} = A \frac{{α}_{D}}{{D}_{B E} + {α}_{D} ( 1 - {γ}_{D} )} + B$$

Therefore, when the ADC 300 converts analog signals to digital signals according to the method 400, the temperature at that point of time can be calculated. Moreover, the calibration temperature (T_{cal}) is a single point of temperature, thus this is one point calibration that can calibrate the error over operating temperature range for both ADC 300 output and temperature output at the same time which significantly reduce the calibration cost.

FIG. 5 is a flow chart of a calibration method of the ADC 500 according to the present invention. In the first step 501, the analog base-emitter voltage (V_{BE}) is converted by the quantizer 201 which uses the differential base-emitter voltage (ΔV_{BE}) as the reference voltage (V_{REF}), wherein the analog base-emitter voltage (V_{BE}) is generated from a BJT or a diode. The result of the said conversion is the digital output code D_{BETcal}. In the second step 602, the digital output code of calibration temperature (D_{Tcal}) in Kelvin unit is calculated by using the following equation:

$${D}_{T c a l} = A \frac{{α}_{D}}{{D}_{B E T c a l} + {α}_{D} ( 1 - {γ}_{D} )} + B$$

In the third step 503, the calibration temperature (T_{cal}) is measured by an external reference temperature sensor of a calibration system. In the fourth step 504, the correction factor (γ) is calculated by using the following equation:

$$γ = \frac{1}{\frac{{D}_{T c a l} - B}{A}} - \frac{1}{\frac{{T}_{c a l} - B}{A}}$$

Finally, in the fifth step 505, the correction factor (γ) is stored in the non-volatile memory unit 306 of the digital module 302.

FIG. 6. shows the effective result of reference voltage (V_{BG}) after trimming according to the invention. Since the present invention does not include an actual analog bandgap voltage to be the reference voltage of ADC, the bandgap voltage reference of the invention will be calculated by the bandgap voltage equation with the correction factor (γ) which results in the reduction of IC process variation.

1. A method for converting analog signals to digital signals comprising:
applying a first analog signal (Vᵢₙ) and a proportional to absolute temperature signal (Vₚₜₐₜ), respectively, to an input terminal and a reference terminal of a quantizer, and calculating a first digital code (Dᵢₙ) using the quantizer;
applying a second analog signal (V_{ctat}) having a complementary to absolute temperature characteristic and the proportional to absolute temperature signal (Vₚₜₐₜ), respectively, to the input terminal and the reference terminal of the quantizer, and calculating a second digital code (D_{ctat}) using the quantizer; and
calculating a digital output code (D_{OUT}) for the first analog signal (Vᵢₙ) using a mathematical function of the first digital code (Dᵢₙ), the second digital code (D_{ctat}), and a digital gain factor (α_{D}).

2. The method of claim 1, wherein the mathematical function is:
D_{OUT}=*(2^{N}−1).

3. The method of claim 1 or claim 2, wherein the step of calculating the digital output code (D_{OUT}) further comprising:
applying a calibration temperature (T_{cal}) to an analog to digital converter;
applying the second analog signal (V_{ctat}) having a complementary to absolute temperature characteristic and the proportional to absolute temperature signal (Vₚₜₐₜ), respectively, to the input terminal and the reference terminal of the quantizer, and calculating a third digital code (D_{ctat,cal}) using the quantizer;
calculating a digital output code for the calibration temperature (D_{Tcal}) using the following expression:
$${D}_{T c a l} = A \frac{{α}_{D}}{{D}_{c tat , Tcal} + {α}_{D}} + B ,$$
wherein A and B are fitting parameters;
measuring the calibration temperature (T_{cal}) using a reference temperature sensor:
calculating a digital correction factor (γ_{D}) using the following expression:
$${γ}_{D} = ( \frac{1}{\frac{{D}_{T c a l} - B}{A}} - \frac{1}{\frac{{T}_{cal} - B}{A}} ) * ( {2}^{N} - 1 ) ;$$
calculating the digital output code (D_{OUT}) using the following expression:
$${D}_{OUT} = \frac{{D}_{i n}}{{D}_{c t a t + {a}_{D} ( 1 - {γ}_{D} )}} * ( {2}^{N} - 1 ) .$$

4. The method of claim 1 or claim 2, wherein the proportional to absolute temperature signal (Vₚₜₐₜ) is a differential base-emitter voltage (ΔV_{BE}) generated by two bipolar junction transistors.

5. The method of claim 1 or claim 2, wherein the second analog signal (V_{ctat}) having the complementary to absolute temperature characteristic is a base-emitter voltage (V_{BE}) generated by a bipolar junction transistor.

6. The method of claim 1 or claim 2, wherein the proportional to absolute temperature signal (Vₚₜₐₜ) is a differential diode voltage (ΔV_{D}) generated by two junction diodes.

7. The method of claim 1 or claim 2, wherein the second analog signal (V_{ctat}) having the complementary to absolute temperature characteristic is a diode voltage (V_{D}) generated by a junction diode.

8-10. (canceled)
